(19) United States
(12) Patent Application Publication
(10) Pub. No.: US 2019/0203378 A1
(43) Pub. Date: Jul. 4, 2019

(54) Methods for Removing a Melt of Silicon from a Crucible and Related Wick Assemblies

(71) Applicant: Corner Star Limited, Kowloon (HK)

(72) Inventors: Bayard K. Johnson, Jefferson Hills, PA (US); Henry Frank Erk, St. Louis, MO (US); Steven Lee Garner, O'Fallon, MO (US); John Gibbons, O'Fallon, MO (US); Anthony Thomas Berhorst, St. Charles, MO (US); Joseph C. Holzer, St. Peters, MO (US); Benjamin Michael Meyer, Defiance, MO (US); Parthiv Daggolu, Creve Coeur, MO (US); Arash Mehdizadeh Dehkordi, St. Peters, MO (US); Shawn Wesley Hayes, Foristell, MO (US)

(21) Appl. No.: 16/223,386

(22) Filed: Dec. 18, 2018

Related U.S. Application Data
(60) Provisional application No. 62/612,079, filed on Dec. 29, 2017.

(51) Int. Cl. C30B 15/30; C30B 29/06

(52) U.S. Cl. CPC C30B 15/30; C30B 29/06

(57) ABSTRACT

Methods for removing a melt of silicon from a crucible used in a silicon ingot growth process and associated wick assemblies are disclosed. The wick is made of porous carbon that ignites upon reaching an ignition temperature causing relatively rapid and relatively large volume take-up of silicon from the crucible.

### CROSS-REFERENCE TO RELATED APPLICATION

This application claims the benefit of U.S. Provisional Patent Application No. 62/612,079, filed Dec. 29, 2017, which is incorporated herein by reference in its entirety.

### FIELD OF THE DISCLOSURE

The field of the disclosure relates to methods for removing a melt of silicon from a crucible and, in particular, methods from removing a silicon melt from a crucible to allow the crucible to be re-used for ingot growth. The field of the disclosure also relates to wick assemblies for removing melts and, in particular, heat-shielded wick assemblies and wick assemblies that incorporate ampoule devices.

### BACKGROUND

Single crystal silicon is commonly prepared by the so-called Czochralski (Cz) process. In such processes, a seed crystal is dipped in a pool of silicon melt and pulled upward to withdraw a single crystal silicon ingot from the melt. The silicon melt is held within a crucible within the crystal puller. In Continuous Czochralski processes (CCz), molten or granular polysilicon is continuously added to the crucible. In Batch Recharge Czochralski methods (BRCz), after a single ingot is grown and removed, silicon is added to the crucible without removing the crucible from the crystal puller and the batch crystal growth process is repeated.

Due to the segregation coefficient of various impurities such as iron, nickel and chromium, these impurities are taken up by the growing ingot at a rate that is small compared to typical rates of addition to the melt which causes the impurities to become increasingly concentrated in the melt. These impurities may be introduced from a variety of sources including the impurities in feed polysilicon, from the crucible or from other components within the puller (e.g., the susceptor which holds the crucible, the heater, and the like).

As the concentration of impurities increases in the melt, the concentration of the impurities in the crystal also rises. Such impurities reduce the minority carrier lifetime of the crystal resulting in decreased efficiency in the resulting devices. The continuous crystal growing process is often terminated when the minority carrier lifetime becomes unacceptable.

Typically, crucibles and other components used in crystal growing processes cannot be reused once a puller is shut down. To remove the melt and crucible after a run is terminated, the system is cooled which causes the silicon melt to expand and destroy the crucible and which may damage other consumable components in the crystal puller system. Termination of the continuous Czochralski process is also time-consuming and labor-intensive due to the complexity of tear-down and assembly and due to the time involved in ensuring that the system has been properly cleaned before start-up. Termination also may degrade the lifetime of some puller assembly components.

A need exists for methods for removing silicon melts with high impurity concentrations from crystal pullers while the puller remains at or near ingot growth temperatures, methods for growing of ingots that involve such melt extractions and for wick assemblies that may be used to remove such silicon melts.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for removing a melt of silicon from a crucible. A wick is lowered into the silicon melt. The wick is made of porous carbon. An initial amount of silicon is drawn into the pores of the wick to cause an amount of silicon to react with carbon and release heat. The heat is at least partially retained to cause the wick to increase in temperature. The temperature of the wick is increased until an ignition temperature is reached at which the wick ignites. Additional silicon is drawn into the pores after ignition of the wick.

Another aspect of the present disclosure is directed to a shielded wick assembly for removing silicon from a crucible. The assembly includes a porous carbon wick. The wick has a bottom, top and a sidewall that extends from the top to the bottom. The wick has a vertical axis that extends through the top and the bottom of the wick. A heat shield at least partially surrounds the wick along the vertical axis.

Yet a further aspect of the present disclosure is directed to a wick assembly for removing silicon from a crucible. The assembly includes a porous carbon wick. The wick has a bottom, top and a sidewall that extends from the top to the bottom. The wick has a vertical axis that extends through the top and the bottom of the wick. An ampoule at least partially surrounds the wick along the vertical axis. The ampoule has a bottom and an inflow orifice spaced from the bottom to allow silicon to enter a space between the ampoule and wick.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic cross-section view of a crystal puller and carbon wick assembly;

FIG. 2 is a schematic cross-section view of a crucible and another embodiment of a shielded carbon wick assembly;

FIG. 3 is a schematic of an embodiment of a carbon wick having a vacuum port arrangement;

FIG. 4 is a schematic of an embodiment of a carbon wick having another vacuum port arrangement;

FIG. 5 is a schematic of an embodiment of a carbon wick having yet another vacuum port arrangement;

FIG. 6 is a cross-section of a shielded carbon wick assembly having a ring which supports the wick at an undercut portion of the wick;

FIG. 7 is a front view of a wick supported by a ring and external rods;

FIG. 8 is a front view of a wick supported by vertical pins that extend into the wick;

FIG. 9 is a front view of a shielded carbon wick assembly and an ampoule for preventing back-contamination of the melt;

FIG. 10 is a graph of the thermal profile of two wicks with different diameters used to withdraw silicon under the conditions of Example 1;

FIG. 11 is a graph of the thermal profile of a wick with and without a heat shield used to withdraw silicon under the conditions of Example 2;

FIG. 12 is a graph showing the weights of porous carbon wicks during silicon extraction for different diameter wicks; and

FIG. 13 is a graph showing the weight of a porous carbon wick during extraction.

Corresponding reference characters indicate corresponding parts throughout the drawings.

### DETAILED DESCRIPTION

Provisions of the present disclosure relate to methods for removing a melt of silicon from a crucible such as a crucible used to produce single crystal silicon ingots by the Czochralski process. In various embodiments, a carbon wick is lowered into the silicon melt causing the wick to ignite and draw up silicon into the wick to deplete the crucible of silicon. The silicon loaded wick may then be removed and the crucible used for further ingot growth. A second wick may be used to remove additional silicon if the wick capacity is less than the amount of silicon to be removed.

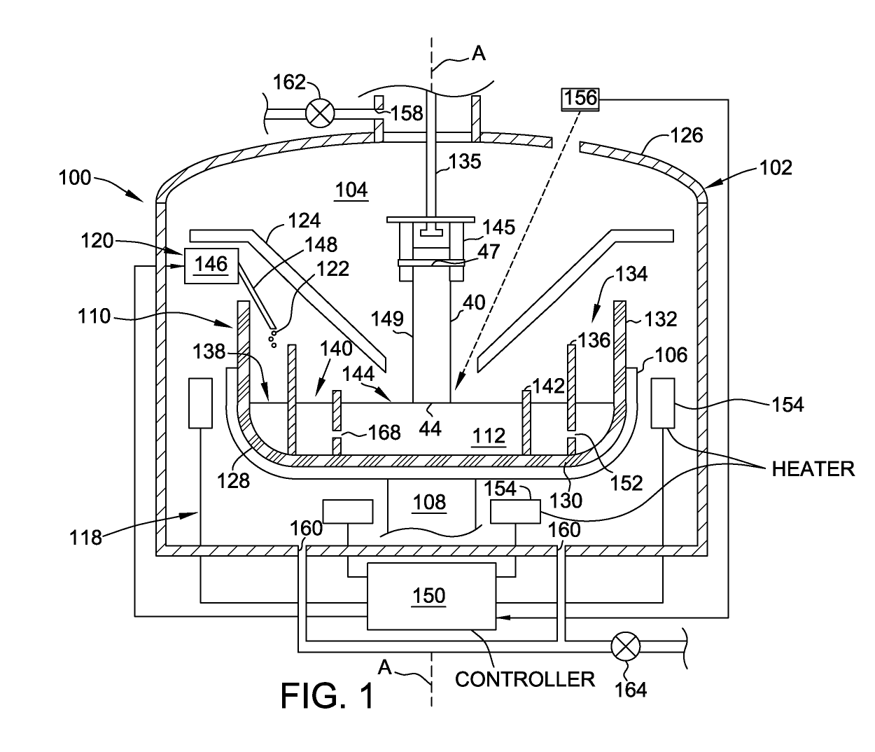

With reference to FIG. 1, a continuous crystal puller 100 has a vertical axis A that coincides with the direction in which a crystal ingot is pulled. The illustrated crystal puller 100 includes a housing 102 defining a growth chamber 104, a susceptor 106 supported by a rotatable shaft 108, a crucible assembly 110 that contains a melt 112 of semiconductor or solar grade material within a crucible 128. The housing 102 encloses the susceptor 106, the crucible assembly 110, and portions of the heating system 118 within the growth chamber 104. The housing 102 includes an upper dome 126, which may include one or more view ports to enable an operator to monitor the growth process. In use, the housing 102 may be used to seal the growth chamber 104 from the external environment. Suitable materials from which the housing 102 may be constructed include, but are not limited to, stainless steel.

In the illustrated embodiments, the crucible assembly 110 includes partitions and multiple zones; however, in other embodiments a two-walled or single-walled crucible or other crucible arrangement may be used unless stated differently. As shown, the crucible assembly 110 has three melt zones—an annular outer zone 138, an annular inner zone 140 and a growth zone 144. The crucible assembly 110 includes a base 130 and a generally annular sidewall 132 extending around the circumference of the base 130. Together, the base 130 and the sidewall 132 define a cavity 134 of the crucible 128 within which the melt 112 is disposed. The crucible 128 may be constructed of any suitable material that enables the system 100 to function as described herein including, for example, quartz.

The crucible assembly 110 includes an inner partition 136 that, with the sidewall 132, defines the annular outer zone 138. The growth zone 144 is defined by a central partition 142. The gap between inner partition 136 and the central partition 142 defines the annular inner zone 140.

During crystal growth, granular or molten silicon is continuously added to the outer zone 138 by feed system 120. In the illustrated embodiment, the feed system 120 includes a feeder 146 and a feed tube 148. Feedstock material 122 and/or dopant material may be placed into the outer melt zone 138 from the feeder 146 through the feed tube 148 to replenish the melt 112 and maintain a desired dopant concentration in the melt 112.

Molten silicon weeps through an opening 152 in the inner partition 136 and enters the annular inner zone 140. In the annular inner zone 140 the molten silicon becomes stabilized (e.g., any granular silicon carried over is melted and the temperature stabilized) to allow silicon with a relatively constant temperature to enter the growth zone 144 through an opening 168 formed in the central partition 142.

Growth of a silicon ingot is initiated by lowering a seed crystal into the melt in the growth zone 144 and pulling the seed crystal and attached ingot up into the growth chamber 104. The seed crystal may be secured by a chuck (e.g., chuck 145 shown in FIG. 1) attached to a pull wire 135. A heat shield 124 may be used to reduce heat loss in the crystal puller.

The heating system 118 is configured to melt an initial charge of solid feedstock material (such as chunk polysilicon), and maintain the melt 112 in a liquified state after the initial charge is melted. The heating system 118 includes a plurality of heaters 154 arranged at suitable positions about the crucible assembly 110. The heaters 154 are connected to the controller 150, which controls the electric energy provided to the heaters 154 to control the amount of thermal energy supplied by the heaters 154. In the illustrated embodiment, the controller 150 also controls feed system 120 and the delivery of feedstock material 122 to the melt 112 to control the temperature of the melt 112.

A sensor 156, such as a pyrometer or similar temperature sensor, provides a continuous measurement of the temperature of the melt 112 at the crystal/melt interface of the growing single crystal ingot. Sensor 156 also may be configured to measure the temperature of the growing ingot. Sensor 156 is communicatively coupled with controller 150.

During a Czochralski growth process, a carrier gas may be introduced into the growth chamber 104 through one or more gas inlets 158 to remove evaporated species and particulates from the growth chamber 104. Gas introduced through the gas inlets 158 is exhausted through one or more exhaust outlets 160. Suitable inert gasses include, for example and without limitation, argon, helium, nitrogen, neon, and combinations thereof. The flow rate of gas through the gas inlet 158 (i.e., the inlet flow rate) may be controlled using one or more flow controllers 162. The exhaust outlets 160 are also connected in fluid communication with a pressure controller 164 configured to control an operating pressure within the growth chamber 104 during a growth process.

In this regard, it should be noted that the heating, control and crucible arrangements and devices described herein are exemplary and other heating, control and crucible arrangements and devices for continuous growing of silicon ingots (or for batch recharge as in such embodiments) may be used unless stated otherwise.

Generally ingots are grown in a continuous process in which silicon is continuously or intermittently added to the outer zone 138 while the ingot continues to grow. Ingot growth may continue until the ingot nears the maximum weight or length which may be supported by the ingot puller. At this point the ingot is removed from the puller while the puller chamber is maintained at or near the growth temperature. Ingot growth is then re-initiated. In this regard, use of the term “continuous” in terms of the ingot growth process includes such embodiments in which multiple ingots are grown in a semi-continuous manner and in which silicon is added continuously or intermittently to the crystal puller while growing such ingots.

In other embodiments, a batch recharge method is used in which silicon is added after an ingot is grown and removed from the growth chamber. The crystal puller may be maintained at or near the crystal puling temperature during recharge of silicon material.

According to embodiments of the present disclosure, after the concentration of impurities in the silicon melt has increased to a point that the impurities are taken up by the ingot at an unacceptable rate (or in which the silicon melt otherwise should be removed from the crucible), a wick 40 is lowered into the silicon melt in the growth zone 144. The wick 40 is attached to a chuck 145 which is connected to the pull wire 135. The wick 40 is connected to the chuck 145 by a graphite pin (not shown). The pin may be similar in design to pins used to connect silicon seeds to the chuck.

The wick 40 is made of carbon and is microporous, with a porosity that allows the wick to ignite. In some embodiments, the wick 40 is made from a carbon fiber such as graphite rigid insulation (GRI) board. Such porous carbon material may be made by forming a slurried suspension of fibers (e.g., rayon fibers) and resin and heating to burn out the resin from the material. The composite material is then graphitized. In some embodiments, the wick 40 has a density of from about 0.05 to about 1 g/cm³ and/or a porosity of at least about 60%, at least 70% or at least 80% (e.g., from about 60% to about 99% or form about 80% to about 99% porosity). The microscopic surface area density of the wick (i.e., microscopic surface area to volume) may be less than 0.1 μm⁻¹ such as from about 0.01 μm⁻¹ to about 0.1 μm⁻¹ or from about 0.03 μm⁻¹ to about 0.06 μm⁻¹ or about 0.04 μm⁻¹. In some embodiments, the wick is not carbon felt which is a macroporous material.

The microporous carbon material may be shaped as a cylinder having a vertical axis that extends through the ends of the cylinder. As shown in FIG. 1, the wick 40 includes a bottom 44, top 47 and sidewall 49 that extends from the top 47 to bottom 44.

The carbon wick 40 may include a carbon substrate (i.e., porous bonded carbon) and a graphitic coating on the surface of the substrate. Alternatively or in addition, a portion of the wick sidewall (e.g., a mid-portion that extends above the melt after lowering the wick) may be coated or encased with a ceramic textile to prevent silicon liquid from spraying out from the sides of the wick.

The wick may be contoured such that the portion that contacts silicon has a higher internal carbon surface area than the portion above the silicon melt. Such contouring may be achieved by including bored channels or cuts in the wick that extend upward from the bottom to allow silicon to rush into the wick upon dipping into the silicon melt. Such contouring increases the initial rate of silicon infiltration for a given plunge depth and increases surface area of the carbon-silicon reaction which produces the heat for increasing the wick temperature to ignition.

In some embodiments, the wick is purified such as by contact with a high-temperature halogen gas. Such purification may allow the wick to be more reactive. Alternative or in addition, the carbon in the wick may be activated to increase its internal surface area and promote reaction of the carbon with silicon. A suitable source of activated carbon is carbon lampback. Carbon lampback may be prepared from carbon black that results from incomplete combustion of petroleum products (e.g., FCC tar, coal tar, ethylene cracking tar, etc.) or from other carbon sources such as carbonaceous material (e.g., nutshells, coconut husks, peat, wood, lignite, and coal). The carbon material is activated by pyrolysis under a non-oxygen environment or in steam (from about 600° C. to about 1200° C.) followed by treatment with strong acids or bases (phosphoric acid, potassium hydroxide, sodium hydroxide, calcium chloride or zinc chloride) followed by carbonization at temperatures between about 450° C. and 900° C.

As an alternative to use of activated carbon, a substrate of non-activated carbon may be impregnated or coated with activated carbon (e.g., a slurry of activated carbon and optional binder or dispersant is contacted with the pores or pumped into the pores or poured into perforations formed in the wick). The amount of binder may be selected such that the carbon will not dislodge and be ejected from the wick but allows sufficient contact with the carbon material.

Alternatively, activated carbon may be placed into a carbon felt and wrapped around the wick or packed into openings drilled into the wick.

In some embodiments, activated carbon is dispersed evenly throughout the wick to prevent hot-spots from forming in the wick and/or is dispersed evenly over its length to promote heat generation into the colder zones of the crystal puller.

Carbon thread, rope or tow (carbonized polyacrylonitrile, rayon or petroleum pitch) may be wrapped around the wick or strung through one or more interior channels drilled axially into the wick to promote ignition of the wick. Any channel may have a diameter nearly that of the thread, rope or tow to minimize volume of voids in the wick.

Generally, the wick is lowered into the bulk of the melt rather than merely touching the surface of the melt to allow the wick to ignite as discussed below. In some embodiments, the wick is lowered to at least about 50% of the height, H₁, of the melt, or at least about 75% or even at least about 85% of the height, H₁, of the melt. After lowering, the wick may be spaced from the crucible bottom (e.g., about 1 mm to about 10 mm from the bottom while drawing silicon from the melt and into the wick to increase the interfacial surface area between the wick and the melt (i.e., the bottom of the wick contacts the melt rather than the crucible bottom).

Once the wick 40 is lowered into the melt, an initial amount of silicon is drawn up into the pores of the wick (e.g., the silicon is drawn up into the wick due to capillary action within the pores). As the molten silicon contacts the fiber surfaces within the wick, the silicon reacts with carbon to form silicon carbide (Si+C->SiC). The reaction between silicon and carbon is very exothermic which causes the wick to heat. When the rate of heat generation by exothermic reaction of SiC formation exceeds the rate of heat loss by radiation and conduction, the wick increases in temperature.

As the wick continues to increase in temperature, it may reach an ignition temperature at which silicon rapidly reacts with the carbon and the temperature of the wick begins to rapidly rise. At ignition temperature, the rate of heat production is so much greater than the rate of heat removal (by radiation and conduction) that the SiC formation reaction is at an exothermic run-away. The rapid rise in temperature allows additional portions of the wick to be above the melting temperature of silicon allowing those portions to wick silicon. As the temperature rises, the viscosity of the silicon melt in the wick is reduced which allows additional silicon melt to be pulled up from the crucible and into the pores of the wick. Generally, ignition causes the wick and/or silicon to become incandescent (i.e., the wick may appear to glow). In some embodiments, ignition may occur at reaction rates that generate about 10 W/cm³ within the core of the wick.

A portion of the silicon carbide that forms in the wick upon reaction of silicon and carbon may be solidified which creates a “slush-like” condition within the wick pores, particularly during the induction period (i.e., the period that runs from contact of the wick to the ignition condition). Ignition is believed to counteract the increase in viscosity caused by the slush as the increase of temperature reduces the viscosity of the silicon-silicon carbide mixture within the pores of the wick.

The rate at which heat is generated in the wick due to reaction between silicon and carbon after ignition (and also before) is at least equal to (and typically greater than) the rate of heat lost from the wick. This creates a run-away reaction condition in the wick which allows substantially all of the silicon in the crucible to be pulled into the wick.

Generally, silicon within the wick during the induction period is near the melting temperature of silicon (i.e., the drawn up silicon is at a temperature from about 1410° C. to about 1480° C. during initial take-up). After ignition, the silicon in the wick may be at a significantly higher temperature due to the runaway condition of the exothermic reaction (e.g., at least 250° C. greater than initial silicon temperature, at least about 500° C. greater, at least about 750° C. greater or even at least about 1000° C. greater than the silicon in the crucible before take-up). Ignition may also heat the remaining silicon in the melt and/or hot-zone components and/or the shield.

The portion of the wick that is initially dipped into the melt has a macroscopic surface area and a macroscopic volume. Generally, wicks with a relatively low ratio of macroscopic surface area to macroscopic volume are more likely to ignite as such wicks have less surface area to radiate away heat. In some embodiments, the wick has a macroscopic surface to volume ratio of 0.025 mm⁻¹ or less or 0.020 mm⁻¹ or less. As referred to herein, “macroscopic” surface area and volume refer to the characteristics of the wick as a whole (i.e., outside dimensions) and excludes any surface area and volume characteristics of the pores of the wick. The surface area of the wick includes all outer surfaces which contact the melt including the sides and bottom of the wick. As the ratio of macroscopic surface area to volume is inversely proportional to the radius of the wick, increasing the radius of the wick reduces the ratio of surface area to volume and improves silicon take-up.

Generally, the ratio of macroscopic surface area to macroscopic volume is bound by the practical diameter of the wick that can be used in the puller (the diameter of the wick cannot exceed the capacity of the crystal puller and hot zone which are typically sized to the nominal diameter of crystal ingot that is pulled during crystal growth). In various embodiments of the present disclosure, the diameter of the wick is at least within about 100 mm of the diameter of the ingots pulled during crystal growth process or at least within about 50 mm, at least about 25 mm or at least within about 10 mm of the diameter of the ingots pulled during crystal growth. In some embodiments, the diameter of the wick is the same diameter of the ingots grown during crystal growth.

As noted above, the wick increases in temperature upon insertion of the wick into the melt during an induction period and then more rapidly increases in temperature after the wick is ignited (and through ignition until the melt is mostly exhausted). Before ignition, the wick rises in temperature at a rate R₁ and increases in temperature after ignition at a rate R₂. The initial rate, R₁, of heat generation may be from about 5 W/cm³ to about 10 W/cm³ and the rate, R₂, of heat generation after ignition may be at least about 20 W/cm³ or even at least about 25 W/cm³. In some embodiments, the ratio of R₂ to R₁ is at least about 1.5 or even at least about 2 or 3. The rate at which silicon is taken up by the wick also increases after ignition of the wick. In some embodiments, the ratio of the rate, Z₁, at which silicon is taken up before ignition to the rate, Z₂, at which silicon is taken up after wick ignition is at least about 5 or even at least about 10 or at least about 15 (e.g., from about 5 to about 25 or from about 5 to about 10).

Generally, the melt extraction process is performed when the silicon liquid surface is at a temperature, T₂, that is at or near the temperature, T₁, at which the crystal puller is maintained during crystal growth (e.g., melt extraction is performed at or above the melting temperature of silicon (about 1410° C.)

In some embodiments, the wick is extrinsically heated (e.g., resistance heater), such as during the induction period. In other embodiments, the wick is not heated and only increases in temperature from the heat of reaction.

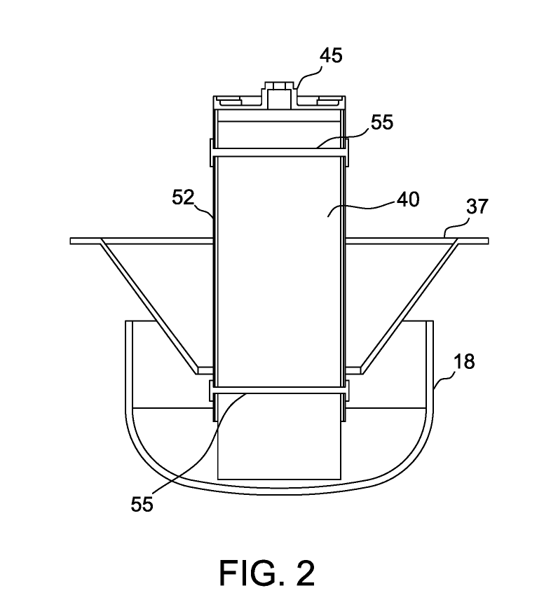

In some embodiments, the wick may be shrouded by a heat shield 52 as in a shielded wick assembly. As shown in FIG. 2 in which the wick 40 is shown dipped into a melt within crucible 18, the heat shield 52 at least partially surrounds the wick 40 along the vertical axis. As shown, the heat shield 52, like the wick 40, is cylindrical and extends from the top 47 (FIG. 1) of the wick 40 and downward along the sidewall 49. Wick shapes other than cylinders may be used such as cones, rectangular blocks and the like. While the wick may be described herein with reference to its diameter, it should be noted that such descriptions may also apply to a dimension associated with a wick of a shape other than a cylinder.

The portion of the wick 40 that is dipped into the melt extends below the heat shield 52. The heat shield 52 is brought to within close proximity of the melt (e.g., about 1 mm to about 10 mm or from about 5 mm to about 10 mm) during melt extraction. The heat shield 52 acts to retain heat in the wick to increase the rate at which silicon is drawn into the wick and also to protect hot zone parts from heat and from emission of silicon from the reacting wick. The heat shield 52 may be made of a variety of materials such as molybdenum, graphite materials (e.g., GRAFOIL), carbon fiber composites (CFC) or aluminum oxide (AlO). In some embodiments, graphite foil is bonded to the wick surface to integrate a heat and splatter shield into the wick.

In some embodiments, the heat shield 52 may include several concentric layers or rings. The rings may be made of the same material or of different materials. The heat shield 52 may be a composite material that includes one or more coatings of reflective material. The inner surface of the heat shield 52 may reflect radiant energy back to the wick and the other portions may be insulating to prevent heat loss to the crystal puller. The shield 52 may include several separate layers such as an outer insulating layer, carbon fiber composite tube or graphite tube substrate layer and/or coating layer.

The heat shield 52 may include exhaust ports that allow generated gas (e.g., SiO) to be removed from the wick and/or may include vacuum ports for applying a vacuum to the wick to remove the gas.

As shown in FIG. 2, the wick 40 may be secured to the heat shield 52 by several pins 55 that assist to support the weight of the wick 40 after loading with silicon. The heat shield 52 may contact the wick 40 as shown in FIG. 2 or there may be an annular space between the wick and the heat shield. The pins 55 may be composed of a material that is durable upon repeated contact with silicon and in crystal puller environments such as silicon carbide or graphite.

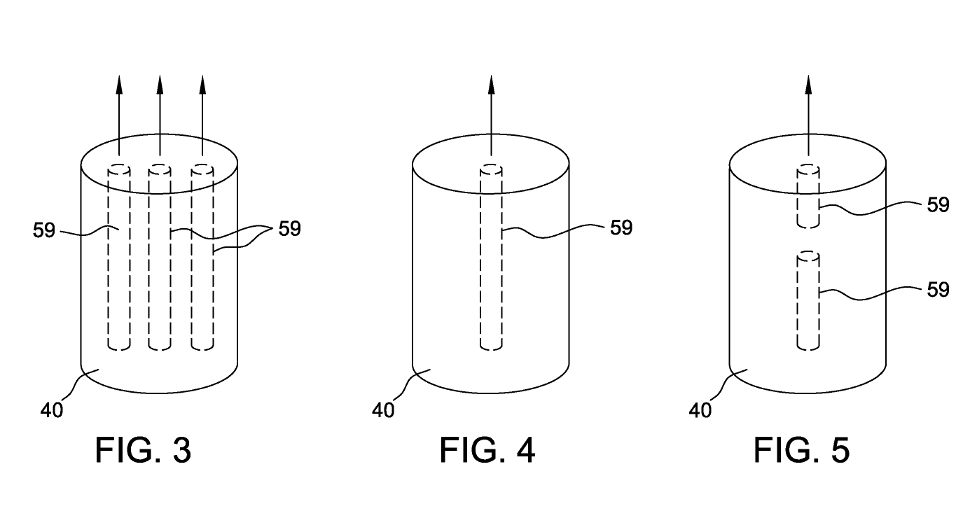

Alternatively or in addition to a heat shield, a vacuum may be applied to the wick to promote drawing of silicon into the wick. This may increase the heat production rate and shorten the induction period. Three different wick arrangements that may be used in accordance with some embodiments of the present disclosure are shown in FIGS. 3-5. The wick 40 includes ports 59 which are connected to a vacuum device (not shown) for a pulling a vacuum (relative to the crystal puller atmosphere). In the arrangement of FIG. 3, the ports 59 extend through the wick to its bottom surface. In the arrangement of FIG. 4, the port 59 extends into the wick but terminates within the wick (i.e., does not fully extend to the bottom surface to prevent the port from quickly plugging with silicon melt). In the arrangement of FIG. 5, the vacuum port 59 is discontinuous in a middle section to prevent molten silicon from being drawn into the vacuum system. The wick 40 may include any suitable size and number of ports (e.g., one, two, three or more ports). The ports 59 may have a constant diameter or may include a number of staggered diameters.

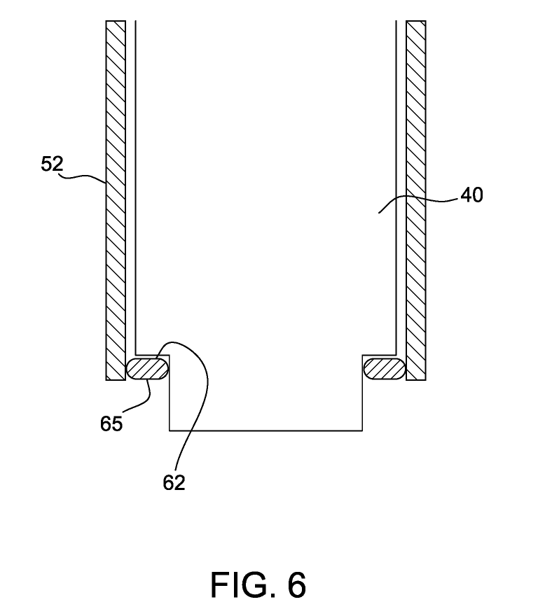

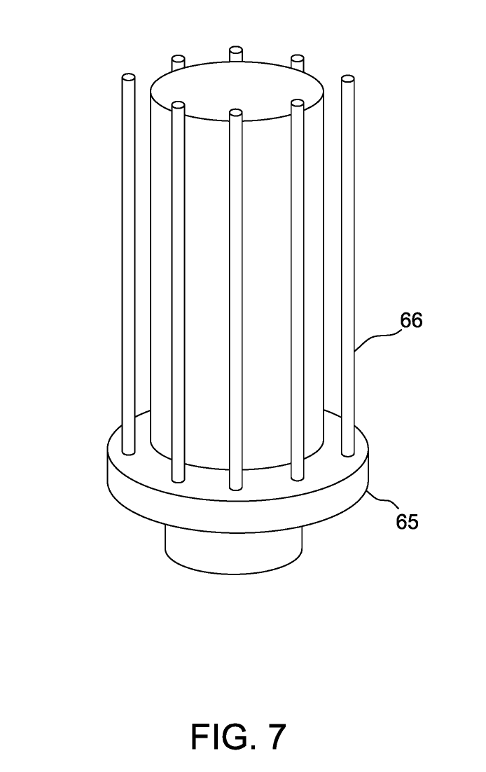

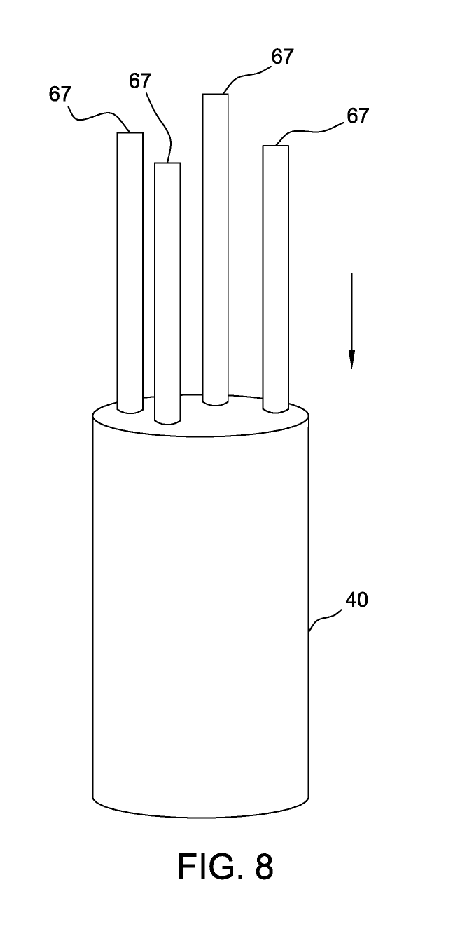

The wick (or shielded wick assembly if a heat shield is used) may include various elements to support the wick as the wick increases by mass upon up-take of silicon. For example and as shown in FIG. 6, the wick 40 may include a smaller diameter portion toward its end that forms a corner 62. A ring 65 is connected to the heat shield 52 to support the wick 40. Fasteners (not shown) may be used to connect the ring 65 to the heat shield 52. The wick 40 may include additional pins that radially extend through the wick 40 and heat shield 52 to further support the wick. The ring 65 may alternatively be connected to external support rods 66 (FIG. 7) rather than an outer shield. In other embodiments and as shown in FIG. 8, vertical pins 67 may extend into the wick 40 to support the wick.

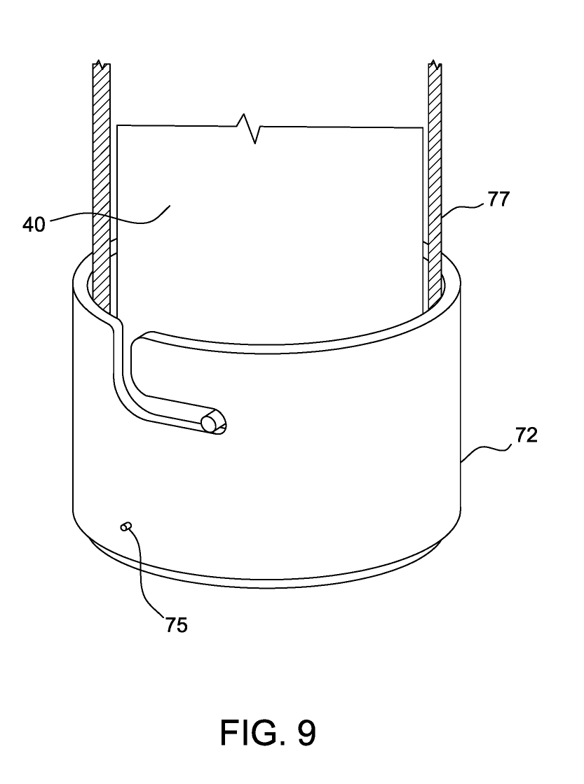

An ampoule device 72 (FIG. 9) may be used in a wick assembly to prevent carbon from cross-contaminating the silicon melt. The ampoule 72 and wick 40 are separated by a sleeve 77 (shown in cross-section in FIG. 9) that supports the ampoule and also isolates the wick from the hot zone of the crystal puller. The sleeve 77 may also route the reaction product gas out of the crystal puller. A portion of the wick 40 extends below the sleeve 77. The ampoule 72 includes an inflow orifice 75 spaced from the bottom of the ampoule 72. Silicon flows into the inflow orifice 75 during silicon take-up. Silicon that is in contact (or near contact) with the wick 40 is prevented from flowing out of the ampoule device 72. Back-flow is prevented as the only opening is orifice 75 which is filled with incoming silicon).

The inflow orifice 75 may be sized to allow for a filling velocity sufficient to prevent back-flow but large-enough to allow the wick to be fed melt at a sufficient rate that does not cause the wick to extinguish. The inflow orifice 75 should be at a vertical position that does not allow silicon to back-flow if it weeps from the wick after extraction but low enough that little silicon remains in the crucible below the position of the orifice 75. The ampoule 72 may be spaced somewhat from the inner crucible to prevent the ampoule and crucible from fusing.

The ampoule 72 may be made of any material that withstands the temperatures of the extraction process without contaminating the melt such as quartz. The sleeve 77 may be made of quartz, silicon carbide or graphite or another suitable material that does not off-gas when heated.

After the wick draws up silicon, the silicon carbide that forms may be allowed to harden and the wick raised from the crucible. The wick may be disposed of or recycled to produce other silicon carbide components. In some embodiments, the wick (and ampoule in embodiment in which an ampoule is used) is maintained at its position in the crucible after extraction for a period to allow silicon that has entered the wick to be further pulled up into the wick. This allows voids to be created toward the bottom of the wick which may accommodate any drip back of material while silicon hardens in the wick.

Compared to conventional methods for extracting a silicon melt from a crucible, the methods of the present disclosure have several advantages. By using a carbon material that is porous (as opposed to less porous materials such as a carbon felt), silicon may be initially wicked up by capillary action which increases the contact area between silicon and carbon and causes the material to heat. By using a material that has a relatively low ratio of macroscopic surface area to volume (i.e., generally a larger diameter wick), heat may be better retained in the wick which may allow the wick to increase in temperature and reach an ignition temperature at which a thermal runaway reaction condition occurs. By using a material that has a relatively low ratio of microscopic surface area to microscopic volume, heat generation may be increased. Ignition allows the wick to rapidly increase in temperature, thereby preventing freezing of silicon and also reducing the viscosity of the drawn-up silicon and/or silicon carbide slush which allows additional silicon to be wicked up rapidly by capillary action. Use of a porous ignitable carbon material allows silicon material to be sucked up by capillary action (i.e., the crucible is emptied) without the wick contacting the bottom of the crucible. By dipping the porous carbon wick into the silicon melt rather than only contacting the surface of the melt, silicon is more rapidly taken up during the induction period which reduces the induction time and increases the overall heat generation rate. In embodiments in which the wick has been purified (such as by contact with a high temperature halogen gas), the wick may be more reactive.

In embodiments in which the extraction process is performed at or near the temperature at which the crystal growth process is performed, the crystal puller parts experience less wear during extraction increasing their lifetime. Performing extraction at or near the temperature at which the crystal growth process is performed also allows the crucible and other consumable components in the crystal puller system to be preserved for subsequent crystal growth.

In embodiments in which the temperature of the melt is lowered during melt extraction, the generation of silica is reduced which improves subsequent ingot LZD performance, reduces occlusion of the camera port caused by SiO “smoke” generation (less change of diameter control issues) and pyro temperature monitoring is made more accurate.

### EXAMPLES

The processes of the present disclosure are further illustrated by the following Examples. These Examples should not be viewed in a limiting sense.

### Example 1: Comparison of Thermal Environment Between Wicks with Different Macroscopic Surface Area to Volume Ratios

A wick made of microporous carbon was lowered into a crucible to extract the silicon melt in a crystal puller used to produce 200 mm silicon ingots by a continuous Czochralski process (cCz). The wick had a diameter of 80 mm. Another melt extraction run was performed with a wick having similar characteristics but having a 200 mm diameter. The 80 mm wick had a macroscopic surface area to volume ratio (of the portion of the wick dipped into the melt) of 0.05 mm⁻¹. The 200 mm diameter wick had a surface area to volume ratio (of the portion of the wick dipped into the melt) of 0.02 mm⁻¹. The wicks had a density from about 0.1 to about 0.2 g/cm³, a porosity of about 90% and a microscopic surface area to volume ratio of less than about 0.1 μm⁻¹.

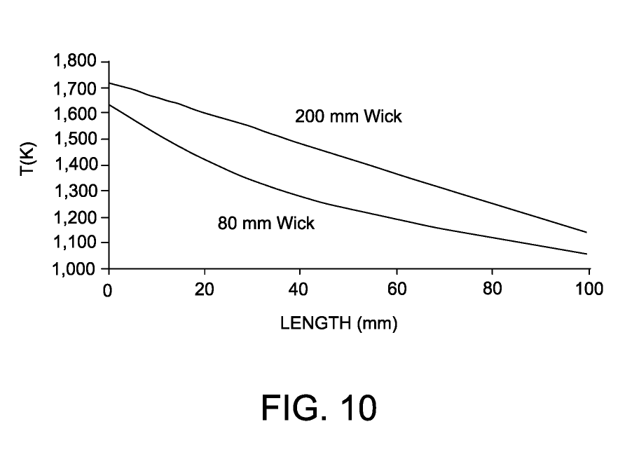

Simulated steady-state temperature profiles along the axis of the wick (0 being the bottom of the wick) for two different diameter wicks that are in contact with the liquid just before infiltration starts are shown in FIG. 10. As can be seen from FIG. 10, the 200 mm diameter wick was hotter across the first 100 mm of length which indicates that the wick was better at retaining heat and promoting ignition and take-up of silicon.

### Example 2: Comparison of Thermal Environment Between Wicks with and without Heat Shield

Simulated temperature profiles were obtained for a shielded wick assembly having a 200 mm wick that was microporous carbon and that was shrouded by a molybdenum heat shield. Another simulation was performed for a wick without a heat shield.

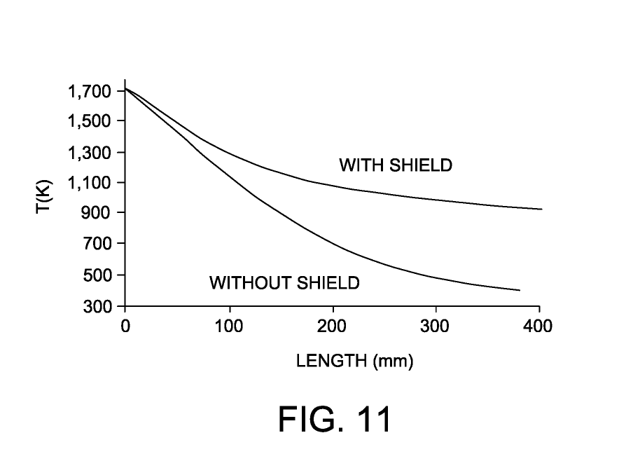

Simulated steady-state temperature profiles along the axis of the wick as the wicks are in contact with the liquid just before infiltration starts are shown in FIG. 11. As can be seen from FIG. 11, the shielded wick was hotter across its length to over 400 mm which indicates that the wick was better at retaining heat and promoting ignition and take-up of silicon.

### Example 3: Rate of Silicon Take-Up for Different Wick Diameters

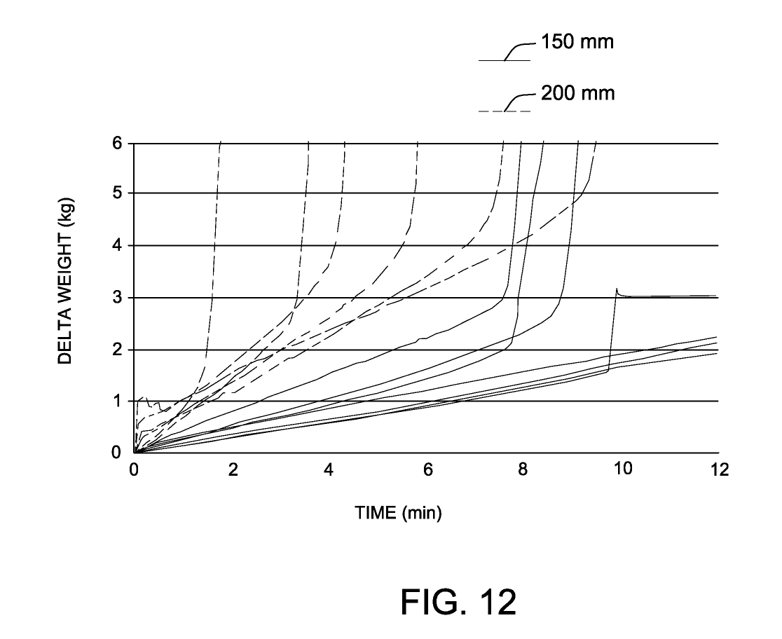

Several wicks made of microporous carbon having different diameters were used to extract a silicon melt from a crystal puller used to produce 200 mm silicon by a continuous Czochralski process (cCz). The wicks had a density from about 0.1 to about 0.2 g/cm³, a porosity of about 90% and a microscopic surface area to volume ratio of less than about 0.1 μm⁻¹. FIG. 12 shows the weight of the wicks as measured during the extraction processes. As shown in FIG. 12, wicks with a larger diameter (about 200 mm in diameter) generally took up silicon more quickly during the induction period and were more likely to ignite relative to smaller diameter wicks (about 150 mm in diameter).

### Example 4: Rate of Silicon Take-Up During Extraction

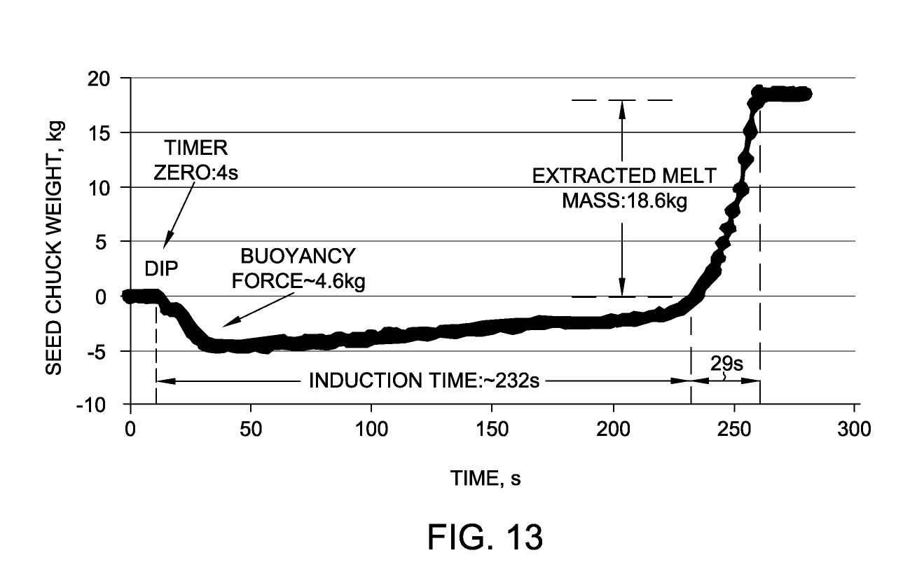

A wick made of microporous carbon was lowered into a crucible to extract the silicon melt in a crystal puller used to produce 200 mm silicon by a continuous Czochralski process (cCz). The wick had a density from about 0.1 to about 0.2 g/cm³, a porosity of about 90% and a microscopic surface area to volume ratio of less than about 0.1 μm⁻¹. The wick was dipped about 25 mm deep into the silicon melt and lowered to about 10 mm from the crucible bottom. FIG. 13 shows the weight of the wick as measured during the extraction process. The wick was reduced in weight after dipping at about 4 seconds due to buoyancy of the wick in the silicon melt. Silicon continued to be drawn into the wick during an induction period of about 232 seconds. At about 175 seconds the reaction and up-take nearly stopped (as shown when the curve nearly levels out). After the induction period, the wick ignited (i.e., the thermal runaway of the SiC reaction) and silicon was rapidly drawn into the wick for 29 seconds until it was depleted.

### Example 5: Continuous Czochralski Ingot Growth and Melt Extraction

Several continuous Czochralski crystals were pulled in a 200 mm crystal puller. The tail end of the last ingot had a minority carrier lifetime of 600 μ-s (at MCD=1×10¹⁵ cm⁻³, resistivity=2 to 3 ohm cm, p-type silicon) by measurements on slugs of crystal sections using a Sinton BCT-400 lifetime tester. A drain crystal was pulled to empty the inner crucible to between. 8 and 9 kg of melt. Six rectangular wicks (6″×6″×1″ thick) of microporous carbon were blocked together to form a 6″×6″×6″ block. The wicks had a density from about 0.1 to about 0.2 g/cm³, a porosity of about 90% and a microscopic surface area to volume ratio of less than about 0.1 μm⁻¹.

Two of these wicks were used in succession for extraction. The density of the wick material was about 0.19 g/cm and the wicks were an Americarb RG-18 structure. The first block was supported by a tungsten pin and lowered into the pull chamber. The wick ignited, reacted and extracted about 5 kg of melt. The tungsten pin melted, but the structure remained intact.

A second block (formed in the same manner as the first) was supported by a carbon pin and lowered into the crucible. The second block ignited, reacted and extracted all the remaining melt, pulling the inner crucible dry. This block remained intact. The second block was removed and polysilicon feeding commenced, filling the inner crucible to normal operating level. A seed was dipped and a crystal was pulled in the first attempt with no loss of zero dislocation (LZD) issues. The minority carrier lifetime of slugs of crystal segments from the seed end of this crystal was measured with Sinton BCT-400 under similar conditions to the earlier crystal and found to be over 1400 μ-s (essentially the starting minority carrier lifetime for this arrangement). The carbon content for both crystals was 0.2 to 0.4 ppma and there was no notable quality difference observed between the two crystals. This suggests that no significant carbon was added with the use of the two wicks.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for removing a melt of silicon from a crucible, the method comprising:
lowering a wick into the silicon melt, the wick being made of porous carbon;
drawing an initial amount of silicon into the pores of the wick to cause an amount of silicon to react with carbon and release heat, the heat being at least partially retained to cause the wick to increase in temperature;
increasing the temperature of the wick until an ignition temperature is reached at which the wick ignites; and
drawing additional silicon into the pores after ignition of the wick.

2. The method as set forth in claim 1 wherein heat is generated at a rate R₁ while drawing an initial amount of silicon into the pores of the wick to cause an amount of silicon to react with carbon and release heat and heat is generated at a rate R₂ after ignition, the ratio of R₂ to R₁ being at least about 1.5.

3. The method as set forth in claim 1 wherein the viscosity of the silicon melt in the pores is reduced after ignition to cause additional silicon melt to be pulled up from the crucible and into the wick.

4. The method as set forth in claim 1 wherein a portion of silicon that is drawn into the wick reacts with carbon to form silicon carbide.

5. The method as set forth in claim 1 wherein the crucible has a bottom, the wick being spaced from the bottom while drawing silicon from the melt and into the wick.

6. The method as set forth in claim 1 wherein the wick is porous bonded carbon fiber.

7. The method as set forth in claim 1 wherein the wick and/or silicon becomes incandescent upon ignition.

8. The method as set forth in claim 1 wherein the wick is partially encased by a heat shield.

9. The method as set forth in claim 1 wherein the wick comprises a carbon substrate and a graphitic coating on the surface of the substrate.

10. The method as set forth in claim 1 further comprising applying a vacuum to the wick to promote drawing of silicon into the wick.

11. The method as set forth in claim 1 wherein the wick is encased by an ampoule, the ampoule comprising an inflow orifice that allows silicon to enter a space between the ampoule and wick.

12. The method as set forth in claim 1 wherein the wick is made of microporous carbon.

13. The method as set forth in claim 1 wherein the surfaces of the porous carbon wick are activated.

14. A method for growing silicon ingots in a crystal puller comprising a crucible, the method comprising:
providing a first source of silicon material into the crucible to form a silicon melt;
withdrawing a first ingot from the silicon melt;
terminating ingot growth, a pool of silicon remaining in the crucible after termination of ingot growth;
removing the pool of silicon by the method of claim 1;
adding a second source of silicon material into the crucible without removing the crucible from the crystal puller after the pool of silicon is removed; and
withdrawing a second ingot from the silicon melt.

15. A shielded wick assembly for removing silicon from a crucible, the assembly comprising:
a porous carbon wick, the wick having a bottom, top and a sidewall that extends from the top to the bottom, the wick having a vertical axis that extends through the top and the bottom of the wick; and
a heat shield that at least partially surrounds the wick along the vertical axis.

16. The shielded wick assembly as set forth in claim 15 wherein the wick is connected to the heat shield.

17. The shielded wick assembly as set forth in claim 15 wherein the heat shield extends from the top of the wick and downward along the one or more sidewalls and a portion of the wick extends below the heat shield.

18. The shielded wick assembly as set forth in claim 15 wherein the wick is made of microporous carbon.

19. A wick assembly for removing silicon from a crucible, the assembly comprising:
a porous carbon wick, the wick having a bottom, top and a sidewall that extends from the top to the bottom, the wick having a vertical axis that extends through the top and the bottom of the wick; and
an ampoule that at least partially surrounds the wick along the vertical axis, the ampoule having a bottom and an inflow orifice spaced from the bottom to allow silicon to enter a space between the ampoule and wick.

20. The wick assembly as set forth in claim 19 comprising a sleeve that supports the ampoule and shields the wick from the crystal puller.
